(19) United States
(12) Patent Application Publication
(10) Pub. No.: US 2008/0290468 A1
(43) Pub. Date: Nov. 27, 2008

(54) STRUCTURE OF FLEXIBLE ELECTRONICS AND OPTOELECTRONICS

(75) Inventors: Chee-Wee LIU, Taipei City (TW); Y. -T. CHIANG, Taipei City (TW); M. H. LEE, Taipei City (TW); Y. DENG, Taipei City (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: NATIONAL TAIWAN UNIVERSITY, Taipei City (TW)

(21) Appl. No.: 11/937,217

(22) Filed: Nov. 8, 2007

(30) Foreign Application Priority Data
May 25, 2007 (TW) 096118874

(51) Int. Cl. H01L 23/00; H01L 21/00

(52) U.S. Cl. 257/616; 257/702; 438/125; 257/E23.002; 257/E21.002

(57) ABSTRACT

A method for producing a flexible electronic device is provided. The method comprises steps of providing a flexible substrate, forming an inorganic film on the flexible substrate and etching the inorganic film to obtain an electronic element of the electronic device. In another aspect, a flexible electronic device is provided. The flexible electronic device comprises a flexible substrate and an inorganic film disposed on the flexible substrate and having an electronic element, wherein the electronic element is formed by etching the inorganic film.

### FIELD OF THE INVENTION

The present invention relates to a structure of flexible electronics and optoelectronics. Particularly, the present invention relates to a structure of flexible electronics and optoelectronics having an electronic element made of inorganic silicon or germanium.

### BACKGROUND OF THE INVENTION

Generally, the electronic element of a flexible electronic device is made of an organic polymer material. Although there are various organic polymer materials with well efficiency, but they still have limitation in lifespan, and their manufacture is more complex and difficult. A film layer transfer technology for separating a surface from a substrate is a prior art, but it has not been used in the flexible electronic device. For example, the U.S. Pat. No. 5,374,564, a Smart-cut process invented by Bruel, is applicable to the film layer transfer between different materials, wherein a hydrogen ion is implanted into the inner layer of a wafer, and the amount of the hydrogen ion is controlled by an implanting concentration while the depth of the implantation is controlled by an implanting energy. Moreover, a wafer-bonding technology can be combined with the hydrogen-ion implantation under a high temperature to cause the split of the wafer.

In order to overcome the drawbacks in lifespan limitation and complex manufacture of the electronic device made of organic polymer, a structure of flexible electronics and optoelectronics are provided based on the inventors' experience in experiments, tests and researches for a long time. Besides overcoming the drawbacks of the prior art described above, the present invention further has the advantages of a longer lifespan electronic device, convenience in material obtainment and a mature manufacturing technology. In other words, the issues to be solved by the present invention are how to overcome the problem of lifespan limitation and complex manufacture of the electronic device made of organic polymer, how to overcome the problem of the connection for transmitting signals between a first and a second elements of the electronic device, and how to overcome the problem of fabricating even more advanced elements after the finish of the electronic device. The summary of the present invention is described as follows.

### SUMMARY OF THE INVENTION

In accordance with an aspect of the present invention, a structure of a flexible optoelectronics is provided. The flexible optoelectronics comprises a flexible substrate and an inorganic film disposed on the flexible substrate and having an electronic element, wherein the electronic element is formed by etching the inorganic film.

According to the invention, the flexible substrate is made of one selected from a group consisting of an organic polymer, a glass and a metal, and the electronic element has a structure selected from a group consisting of a metal-insulator-semiconductor (MIS) structure, a PIN structure and a metal-semiconductor-metal (MSM) structure.

Preferably, the organic polymer is selected from a group consisting of a polyimide, a poly(ethylene naphthalate) and a poly(ethylene terephthalate).

In one preferred embodiment, the inorganic film is a small piece of a surface derived from a host substrate with a hydrogen ion implanted layer on a surface thereof.

Preferably, the host substrate is one of a silicon substrate and a germanium substrate, and the inorganic film is a layer of the one of a silicon and a germanium substrate being transferred from the host substrate.

Preferably, the host substrate is oriented in a direction selected from a group consisting of {100}, {110} and {111}.

Preferably, the host substrate is one of a wafer and a die.

In one embodiment, the electronic device further comprises an organic polymer stacked on the inorganic film and a particular film deposited on the organic polymer, wherein the particular film is etched as a particular electronic element so that the optoelectronics is a multilayer flexible optoelectronics.

Preferably, the multilayer flexible electronic device is one selected from a group consisting of a light detector, a light emitting diode, a solar cell and a complementary metal oxide semiconductor.

In accordance with another aspect of the present invention, a structure of a flexible electronics is provided. The flexible electronics comprises a flexible substrate and a patterned inorganic film mounted on the flexible substrate.

In accordance with a further aspect of the present invention, a method for producing a flexible electronics is provided. The method comprises steps of providing a flexible substrate, forming an inorganic film on the flexible substrate, and etching the inorganic film to obtain an electronic element of the electronic device.

According to the invention, the method further comprises steps of providing a host substrate, forming a hydrogen ion-cut layer in the host substrate, connecting the host substrate and the flexible substrate, and separating the hydrogen ion-cut layer from the host substrate as the inorganic film formed on the flexible substrate.

According to the invention, the host substrate and the flexible substrate are connected by one of a cohesion and a bonding.

According to the invention, the hydrogen ion-cut layer is separated from the host substrate by heating the host substrate and the flexible substrate to a temperature ranged from 100° C. to 350° C. for a duration ranged from 10 minutes to 15 hours. In one embodiment, the host substrate and the flexible substrate are heating at 150° C. for 9 hours followed by heating at 250° C. for 1 hour.

According to the invention, the method further comprises a step of wet etching a surface of the host substrate to be implanted for reducing the roughness of the surface.

According to the invention, the electronic element comprises a first element and a second element, and further comprises a step of connecting the first and the second elements for sending a signal from the first element to the second element by a lightwave circuit technology.

In one preferred embodiment, the method further comprises steps of stacking one of an organic polymer material and a flexible material on the electronic element, depositing a film on the one of the organic polymer material and the flexible material, and etching the film to form a particular electronic element.

Preferably, the inorganic film is a small piece of a film formed by one selected from a group consisting of a chemical vapor deposition, an inkjet printing, a roll to roll process, a spin-coating and a hydrogen ion-cut process.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIGS. 1(a)-1(d) are diagrams showing a method for producing the flexible electronics according to a preferred embodiment of the present invention;

FIG. 2 is a diagram showing the planar arrangement of the flexible electronics in FIG. 1;

FIG. 3 a diagram showing the electronic structure according to another preferred embodiment of the present invention;

FIG. 4 is a diagram showing the cross sectional view of the electronic structure in FIG. 3 under a bending force;

FIG. 5 is a current-voltage diagram of a light detector made of a germanium film; and

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

### First Preferred Embodiment

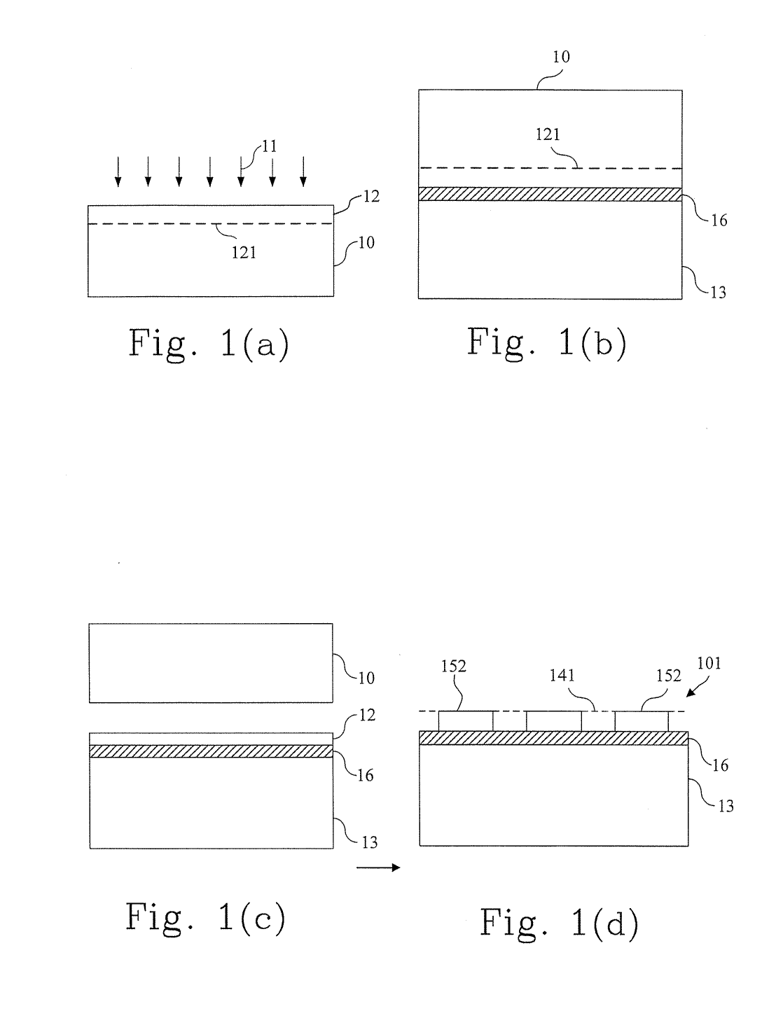

Please refer to FIGS. 1(a)-1(d), which are diagrams showing a method for producing the flexible electronics according to a preferred embodiment of the present invention. In the preferred embodiment, the flexible electronics is a flexible optoelectronics. Firstly, a host substrate 10 is provided for proceeding a hydrogen-ion implantation 11 into a surface 12 of the host substrate 10 (the dotted line 121 indicates an interface of the peak of the hydrogen-ion implantation). Secondly, a flexible substrate 13 is provided for cohering with the host substrate 10, for example, the two substrates can be cohered by using a NANO™ SU-8 2100 photoresist. Moreover, the surface 12 is separated from the host substrate 10 followed by an etching process to obtain an electronic element 152 (the dotted line 141 represents the separated surface 12 after an etching process, wherein the surface 12 is a germanium film). According to the above process, a flexible electronics 101 is obtained.

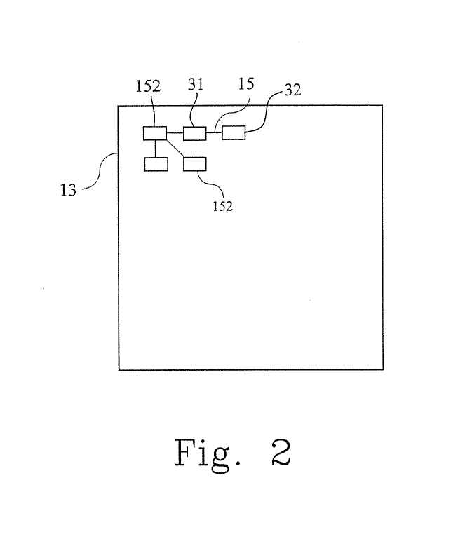

The above process further comprises a step of heating the host substrate 10 and the flexible substrate 13 at 150° C. for 9 hrs to make the implanted hydrogen-ion in the host substrate 10 diffuse slowly. Subsequently, in order to separate the surface 12 from the host substrate 10, the host substrate 10 and the flexible substrate 13 are heating to 250° C. for 1 hr. Of course, the person skilled in the art can alter the heating process to a temperature ranged from 100° C. to 350° C. for a duration ranged from 10 minutes to 15 hrs according to actual situations. As FIG. 2 shows, the reference numeral 15 represents a connection between a first element 31 and a second element 32 of the electronic element. The internal connection 15 of the electronic element 101 sends a signal from the first element 31 to the second element 32 by a lightwave circuit technology. Many small electronic elements, such as the light detector, the solar cell, the complementary metal oxide semiconductor or the light emitting diode (not shown), can be made on the flexible substrate 13 by using the Smart-cut technology.

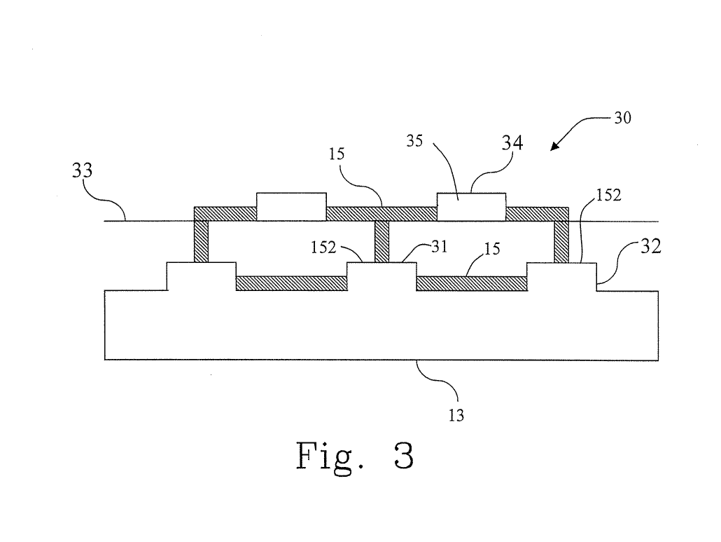

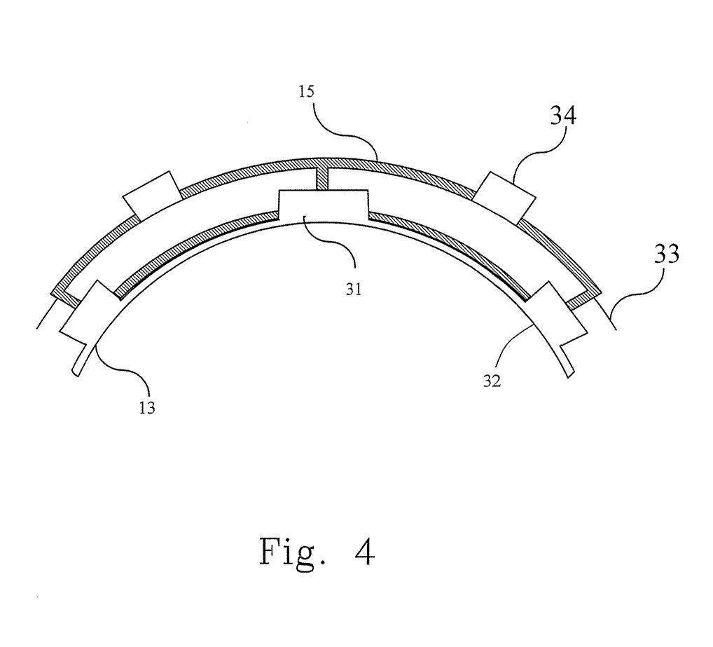

According to the above procedures, a small piece of germanium film on the SU-8 2100 wafer is transferred to a flexible substrate by a wafer bonding technique. Please refer to FIG. 3, wherein the process not only produces the electronic element 152 in a single layer, but affords a multilayer electronics 30 with advanced electronic elements by stacking an organic polymer 33 or a flexible material 33 on the electronic element 152, depositing a film 34 on the organic polymer 33 or the flexible material and etching the film 34 to form a particular electronic element 35. FIG. 4 is a diagram showing the cross sectional view of the multilayer electronics 30 in FIG. 3 under a bending force.

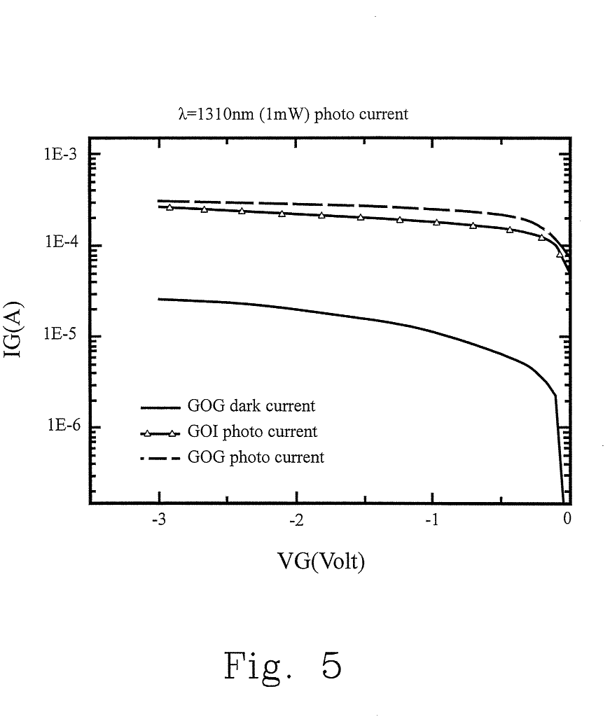

Please refer to FIG. 5, which is a current-voltage diagram of a light detector made of the germanium film 12. In FIG. 5, the middle line and the upper line are plotted according to the data of germanium on insulator (GOI) and germanium on glass (GOG), respectively. It is noted that the germanium film has an apparent photo current indicated by the middle line and the upper line, which is different from the dark current indicated by the lower line. Moreover, a rough surface of the transferred germanium film will be produced owing to the Smart-cut process, and the roughness of the surface 12 can be reduced by wet etching elements on the surface 12. After this wet etching process, some defects generated from the implanting process are removed.

In this embodiment, an n-type germanium wafer substrate 10, named the host substrate, is implanted with a 200 keV, 1.5E17 cm⁻² hydrogen ion 11. The implanted depth is related to the implanted power, and the implanted concentration is related to the temperature and time of the wafer splitting. Another flexible substrate polyimide 13 is named as the handle wafer. These two wafers 10 and 13 are sonicated with acetone for 5 minutes to remove the organic impurities and dust on the surface of the wafers. Then, the handle wafer 13 is coated with the NANO™ SU-8 2100 photoresist by a photoresist coating spinner to obtain a cohesive layer. The coating process includes two steps. In the first step, the handle wafer 13 is rotated at 500 r.p.m. for 10 sec; in the second step, the handle wafer 13 is rotated at 3,000 r.p.m. for 30 sec. Subsequently, a two-step soft bake is applied to the handle wafer 13, where the handle wafer 13 is heated at 65° C. for 5 minutes followed by a 95° C. heating for 20 minutes.

After a 95° C. soft bake for 20 minutes, the respective cohering interfaces of the wafers 10 and 13 are aligned at room temperature to cohere the wafers. The cohered wafers are turned back and then the NANO™ SU-8 2100 photoresist thereof is exposed with ultraviolet of 400 nm wavelength for 110 sec. Subsequently, a Post Exposure Bake, PEB, is carried out in two steps of heating at 65° C. for 5 minutes followed by a 95° C. heating for 100 minutes. The cohered wafers are heated to 150° C. for 9 hrs under a hydrogen purge at 1 atm to slowly diffuse the hydrogen ion in the implanted germanium wafer 10. Then, the cohered wafers are heated to 250° C. for 1 hr to produce a separation at the peak of the hydrogen-ion implantation 121 so that a transferred germanium film is obtained.

According to one point of view, the present invention relates to a structure of a flexible electronics 101, for example, an optoelectronics, which comprises a flexible substrate 13 and an inorganic film 12 disposed on the flexible substrate 13 and having an electronic element 152 of the flexible electronics 101. Certainly, the electronic element 152 is formed by etching the inorganic film 12 of the flexible electronics 101. A surface 12 on the host substrate 10 becomes the inorganic film 12 after separated from the host substrate 10. The host substrate 10 can be bonded to the flexible substrate 13 through a cohesive layer 16 by a wafer bonding technique. The host substrate 10 is a silicon substrate or a germanium substrate, and thus the inorganic film 12 is a piece of silicon or germanium 12 transferred from the host substrate 10. As abovementioned, the implanted hydrogen ion distributes evenly on the surface 12, and the flexible substrate 13 serves as a handle substrate.

The host substrate herein is selected from a group consisting of a monocrystalline, a polycrystalline and a non-crystalline substrate. Moreover, the host substrate 10 herein is selected from a group consisting of a non-doping, a p-type doping and an n-type doping substrate, and the doping concentration can be altered according to actual needs. Further, the host substrate 10 is oriented in a direction selected from a group consisting of {100}, {110} and {111}. Preferably, the host substrate 10 is one of a wafer and a die with any size and any shape. The small sized silicon or germanium 12 forms an electronic frame for enhancing a flexural stress of the electronics. The flexible substrate 13 is made of one selected from a group consisting of an organic polymer, a glass and a metal, and preferably, the organic polymer is selected from a group consisting of a polyimide, a poly(ethylene naphthalate) and a poly(ethylene terephthalate).

Additionally, the present invention also provides a multilayer flexible electronics 30 such as a light detector, a light emitting diode, a solar cell and a complementary metal oxide semiconductor. In the multilayer flexible electronics 30, an organic polymer 33 is stacked on the electronic element 152, and a particular film 34 is deposited on the organic polymer 33, wherein the particular film 34 is etched as a particular electronic element 35. In the flexible electronic device herein, the electronic element 152 has a structure selected from a group consisting of a metal-insulator-semiconductor (MIS) structure, a PIN structure and a metal-semiconductor-metal (MSM) structure. As to other detailed sub-units of the flexible electronic device of the present invention, they are mentioned in the above manufacturing process and are not further explained here.

In another aspect, the present invention also relates to a method for producing a flexible electronics 101. The method comprises steps of providing a flexible substrate 13, forming an inorganic film 12 on the flexible substrate 13 and etching the inorganic film 12 to obtain an electronic element 152 of the flexible electronic device 101. Of course, the method further comprises steps of providing a host substrate 10, forming a hydrogen ion 11 in a surface 12 of the host substrate 10, connecting the host substrate 10 with the flexible substrate 13 and separating the surface 12 from the host substrate 10 as the inorganic film 12 formed on the flexible substrate 10.

Alternately, the step of connecting the substrates 10 and 13 can be substituted by directly bonding the flexible substrate 13 with the host substrate 10. Similarly, the host substrate 10 and the flexible substrate 13 are heated to 150° C. for 9 hrs in order to slowly diffuse the hydrogen ion 11. For example, the hydrogen ion 11 in the surface 12 can be formed by a hydrogen ion implanting process. Further, the implanting process 11 can be substituted by a chemical vapor deposition, an inkjet printing, a roll to roll process, a spin-coating and a hydrogen ion-cut process to obtain the inorganic film 12.

The silicon and germanium materials adopted in the present invention are available easily, and the manufacturing technique thereof is quite mature. Therefore, a semiconductor factory can produce the silicon or germanium element on the flexible substrate 13 by its inherent manufacturing technique and equipment. In the present invention, the silicon and germanium are used to replace the organic polymer in the prior art, and furthermore, the producing method thereof is an integration of inherent manufacturing techniques to obtain a flexible structure. For making a flexible electronics, the silicon or germanium element shall take a flexural stress, and thus it is necessary to produce small sized transferred films and keep them apart for a certain distance. Moreover, the multilayer structure results from stacking an organic polymer repeatedly, and the operation speed of the element 35 is improved by an intrinsic connection between each layer and each element by a lightwave circuit technology.

When a silicon, a germanium or a small film 12 is transferred successfully, a silicon or a germanium element can be produced by a known producing method of silicon or germanium materials, for example, a light detector, a light emitting diode or a solar cell. A signal between the element 31 and the element 32 can be transmitted through a flexural stress-receivable intrinsic connection. Because the speed of transmitting a signal by lightwave is higher than that by electricity, the intrinsic connection produced by a lightwave circuit technology can replace that produced by electricity. Similarly, the lightwave circuit technology can also be applied to the transmitted signal for the intrinsic connection between the electronic element 152 and the particular electronic element 35.

Based on the above embodiments, it is known that the flexible electronics of the present invention is produced through separating a surface from a hydrogen ion-implanted host substrate. Moreover, an advanced electronic element can be produced by stacking an organic polymer on the electronic element.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A structure of a flexible optoelectronics, comprising:
a flexible substrate; and
an inorganic film disposed on the flexible substrate and having an electronic element, wherein the electronic element is formed by etching the inorganic film.

2. The structure of the flexible optoelectronics as claimed in claim 1, wherein the flexible substrate is made of one selected from a group consisting of an organic polymer, a glass and a metal, and the electronic element has a structure selected from a group consisting of a metal-insulator-semiconductor (MIS) structure, a PIN structure and a metal-semiconductor-metal (MSM) structure.

3. The flexible optoelectronics as claimed in claim 2, wherein the organic polymer is selected from a group consisting of a polyimide, a poly(ethylene naphthalate) and a poly(ethylene terephthalate).

4. The structure of the flexible optoelectronics as claimed in claim 1, wherein the inorganic film is a small piece of a surface derived from a host substrate.

5. The structure of the flexible optoelectronics as claimed in claim 4, wherein the host substrate is one of a silicon substrate and a germanium substrate, and the inorganic film is a layer of the one of the silicon and germanium substrate being transferred from the host substrate.

6. The structure of the flexible optoelectronics as claimed in claim 4, wherein the host substrate is oriented in a direction selected from a group consisting of {100}, {110} and {111}.

7. The structure of the flexible optoelectronics as claimed in claim 4, wherein the host substrate is one of a wafer and a die.

8. The structure of the flexible optoelectronics as claimed in claim 1, further comprising:
an organic polymer stacked on the inorganic film; and
a particular film deposited on the organic polymer,
wherein the particular film is etched as a particular electronic element so that the optoelectronics is a multilayer flexible optoelectronics.

9. The structure of the flexible optoelectronics as claimed in claim 8, wherein the multilayer flexible electronic device is one selected from a group consisting of a light detector, a light emitting diode, a solar cell and a complementary metal oxide semiconductor.

10. A structure of a flexible electronics comprising:
a flexible substrate; and
a patterned inorganic film mounted on the flexible substrate.

11. A method for producing a flexible electronics, comprising steps of:
providing a flexible substrate;
forming an inorganic film on the flexible substrate; and
etching the inorganic film to obtain an electronic element of the electronic device.

12. The method as claimed in claim 11, further comprising steps of:
providing a host substrate;
forming a hydrogen ion-cut layer in the host substrate;
connecting the host substrate and the flexible substrate; and
separating the hydrogen ion-cut layer from the host substrate as the inorganic film formed on the flexible substrate.

13. The method as claimed in claim 12, wherein the host substrate and the flexible substrate are connected by one of a cohesion and a bonding.

14. The method as claimed in claim 12, wherein the hydrogen ion-cut layer is separated from the host substrate by heating the host substrate and the flexible substrate to a temperature ranged from 100° C. to 350° C. for a duration ranged from 10 minutes to 15 hours.

15. The method as claimed in claim 14, wherein the temperature is 250° C. and the duration is 1 hour.

16. The method as claimed in claim 15, further comprising:
heating the host substrate and the flexible substrate to 150° C. for 9 hours before the separation.

17. The method as claimed in claim 12, further comprising:
wet etching a surface of the host substrate to be implanted for reducing the roughness of the surface.

18. The method as claimed in claim 11, wherein the electronic element comprises a first element and a second element, and further comprises a step of:
connecting the first and the second elements for sending a signal from the first element to the second element by a lightwave circuit technology.

19. The method as claimed in claim 11, further comprising steps of:
stacking one of an organic polymer material and a flexible material on the electronic element;
depositing a film on the one of the organic polymer material and the flexible material; and
etching the film to form a particular electronic element.

20. The method as claimed in claim 11, wherein the inorganic film is a small piece of a film formed by one selected from a group consisting of a chemical vapor deposition, an inkjet printing, a roll to roll process, a spin-coating and a hydrogen ion-cut process.
